(19) United States
(12) Patent Application Publication
(10) Pub. No.: US 2011/0143550 A1
(43) Pub. Date: Jun. 16, 2011

(54) METHOD FOR MANUFACTURING SEMICONDUCTOR DEVICE, APPARATUS FOR PROCESSING SUBSTRATE, AND COMPUTER READABLE MEDIUM

(75) Inventor: Shunsuke SAITO, Kanagawa (JP)

(73) Assignee: RENESAS ELECTRONICS CORPORATION, Kanagawa (JP)

(21) Appl. No.: 12/969,696

(22) Filed: Dec. 16, 2010

(30) Foreign Application Priority Data
Dec. 16, 2009 (JP) 2009-285694

(51) Int. Cl. H01L 21/302; C23F 1/08

(52) U.S. Cl. 438/750; 156/345.15

(57) ABSTRACT

A method for manufacturing a semiconductor device, including: partially removing a first layer formed on a wafer supported by a support member by supplying a first liquid at a temperature of 60 degrees C. or higher over the wafer (step S1); cooling the wafer after the partially removing the first layer (step S2); and removing the remaining portions of the first layer by supplying the first liquid at a temperature of 60 degrees C. or higher over the wafer after the cooling the wafer, the remaining portions of the first layer being remained after the partially removing the first layer (step S3).

This application is based on Japanese patent application No. 2009-285,694, the content of which is incorporated hereinto by reference.

### BACKGROUND

1. Technical Field

The present invention relates to a method for manufacturing a semiconductor device, an apparatus for processing a substrate, and a computer readable medium.

2. Related Art

In semiconductor manufacturing processes, process cycles consisting of resist coating-etching-resist stripping operations are repeated over a surface of a substrate such as a semiconductor wafer, a glass substrate for liquid crystal display, a glass substrate for plasma display, a glass substrate for field emission display (FED), a substrate for optical disk, a substrate for magnetic disk, a substrate for magneto-optical disk, a substrate for photo mask and the like. Processes of the resist stripping generally fall into two categories, that is: a wet processing, which utilizes an organic solvent or a processing solution composed of a mixture of an aqueous solution of hydrogen peroxide and sulfuric acid and the like, as a stripping liquid; and a dry processing that utilizes a plasma, and the choice of one of the two processes are suitably made depending on applications. According to a comparison of the wet processing and the dry processing, the choice of the wet processing predominates, since the wet processing, in general, is economically advantageous. Typical technologies related to the wet processing include, for example, a technology described in Japanese Patent Laid-Open No. 2007-234,812 and a technology described in Japanese Patent Laid-Open No. 2008-118,088.

Japanese Patent Laid-Open No. 2007-234,812 discloses a process for processing a substrate including the following operations. First of all, a processing solution of a mixture of sulfuric acid and an aqueous solution of hydrogen peroxide is supplied over a surface of a substrate. Then, a state of the substrate, in which the processing solution forms liquid membranes on the surface of the substrate to be remained thereon, is maintained (puddling process). Then, the processing solution is spun off from the substrate via a rotation of the substrate (spinning-off process). Then, the processing solution is supplied again over the surface of the substrate. It is described that, according to such technology, bubbles of water vapor created by a heat generated in a reaction of sulfuric acid and an aqueous solution of hydrogen peroxide continues to be in contact with the same section of the substrate, so that an interference against a removal of a resist in the section in continuous contact with such bubbles can be avoided.

Japanese Patent Laid-Open No. 2008-118,088 discloses a method for manufacturing a semiconductor device, in which a nickel platinum film is formed so as to cover a source/drain diffusion layer formed on a substrate, and then a thermal processing is conducted to induce a reaction between the top section of the source/drain diffusion layer and the nickel platinum film, and then unreacted sections of the nickel platinum film are removed by employing a chemical solution containing hydrogen peroxide at a temperature of not lower than 71 degrees C.

The present inventor has recognized as follows. When a resist stripping is conducted after an ion implantation with higher dose level, a stripping of an unwanted cured layer, which is formed in the resist due to the energy of the ion implantation with higher dose level, requires a processing at higher temperature for longer process time. Further, a stripping process by a wet processing is also employed in a process for selectively removing unreacted sections of a protective film and a nickel (Ni) alloy film in a salicide process, which requires a processing at higher temperature for longer process time.

As such, there is the case that requires continuous and long-time wet processing in order to completely strip the film, depending on the type of the film to be stripped. The implementation of the processing at higher temperature for longer process time causes accelerated deterioration of a support member for supporting a workpiece, such as, for example, a wafer chuck with clamping pins for retaining a wafer thereon and the like.

The technology described in Japanese Patent Laid-Open No. 2008-118,088 involves a single and continuous implementation of a wet processing employing a chemical solution at a temperature of 71 degrees C. as a wet processing for a single wafer. This may also possibly cause the above-described accelerated deterioration of the support member for supporting a wafer and the like.

The technology described in Japanese Patent Laid-Open No. 2007-234,812 involves two separated wet treatments for a single wafer. However, the wafer and the peripheral elements and the like are not sufficiently cooled in a first puddling process and a first spinning-off process conducted between the respective wet processing operations. In such case, the state of the increased temperature of the wafer and the peripheral members are maintained over a long period. Thus, this technology also causes the above-described accelerated deterioration of the support member for supporting a wafer and the like.

### SUMMARY

According to one aspect of the present invention, there is provided a method for manufacturing a semiconductor device, including: partially removing a first layer formed on a wafer supported by a support member by supplying a first liquid at a temperature of 60 degrees C. or higher over the wafer; cooling the wafer after the partially removing the first layer; and removing the remaining portions of the first layer by supplying the first liquid at a temperature of 60 degrees C. or higher over the wafer after the cooling the wafer, the remaining portions of the first layer being remained after the partially removing the first layer.

According to another aspect of the present invention, there is provided an apparatus for processing a substrate, comprising: a support member for supporting a wafer; a motor for rotating the support member; a supplying unit for supplying a liquid over the wafer; and a controller unit for controlling a type of a liquid supplied from the supplying unit and a duration time of the supply, wherein the controller unit provides a control, in which a first liquid is supplied over the wafer for a predetermined time, and then a liquid at a temperature of lower than the temperature of the wafer is supplied over the wafer for a predetermined time, and then the first liquid is supplied over the wafer for a predetermined time.

According to further aspect of the present invention, there is provided a computer readable medium storing a computer program product configured to perform a computer-implemented method for manufacturing a semiconductor device, including: partially removing a first layer formed on a wafer supported by a support member by supplying a first liquid at a temperature of 60 degrees C. or higher over the wafer; cooling the wafer after the partially removing the first layer; and removing the remaining portions of the first layer by supplying the first liquid at a temperature of 60 degrees C. or higher over the wafer after the cooling the wafer, the remaining portions of the first layer being remained after the partially removing the first layer.

The method according to the present invention involves two or more separate implementations of removing the first layer formed on the wafer supported by the support member by supplying a first liquid at a temperature of 60 degrees C. or higher over the wafer; The method further involves an operation for cooling the wafer heated by the supply of the first liquid after each of the two or more implementations of removing the first layer by supplying the first liquid.

Such processing achieves reduced time for continually exposing the wafer and the support member for supporting the wafer over the condition of an elevated temperature due to the heating.

In general, a continuous temperature elevation of the wafer is caused during the continuous supply of the first liquid, depending upon the temperature of the first liquid. On the contrary, the present invention achieves reduced duration time for continually supplying the first liquid over the wafer, such that the highest reachable temperature of the wafer by the heating can be reduced. In such case, the highest reachable temperature of the support member for supporting the wafer can also be reduced. As a result, inhibitions for accelerated deterioration of the support member caused by the exposure to the high temperature condition and for accelerated deterioration of the support member caused by the continuous exposure to the elevated temperature condition over longer period can be achieved.

According to the present invention, accelerated deterioration of the support member for supporting the wafer can be inhibited.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic diagram of an apparatus for processing a substrate of an embodiment according to the present invention;

FIG. 2 is a flow chart, showing an example of a method for manufacturing a semiconductor device of an embodiment according to the present invention;

FIG. 3 a flow chart, showing an example of a method for manufacturing a semiconductor device of an embodiment according to the present invention;

FIG. 4 is a graph, showing a relation of accelerated deterioration of a support member over temperature of a SPM solution in an embodiment;

FIG. 5 is a graph, showing temperature changes of the wafers in a processing for supplying a SPM solution and in the rinse processing; and

FIG. 6 is a graph, showing a relation of accelerated deterioration of the support member over a processing time for continuous supplying a SPM solution in an embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical reference numeral is assigned to an identical element, and the description thereof will not be presented.

Here, each elements composing an apparatus for processing a substrate in each of embodiments may be achieved by an arbitrary combination of a hardware and a software, typically including, a central processing unit (CPU), a memory, a computer program loaded to a memory (including a pre-installed program that is factory-installed in a memory, and in addition, programs loaded from a storage medium such as a compact disc (CD) and the like or downloaded from a server on the internet and the like), a storage unit such as a hard disk for storing such program, and an interface for network connection, of an arbitrary computer. It is understandable for a person having ordinary skills in the art that various types of modified embodiments for the implementation of the invention and the apparatus may be available.

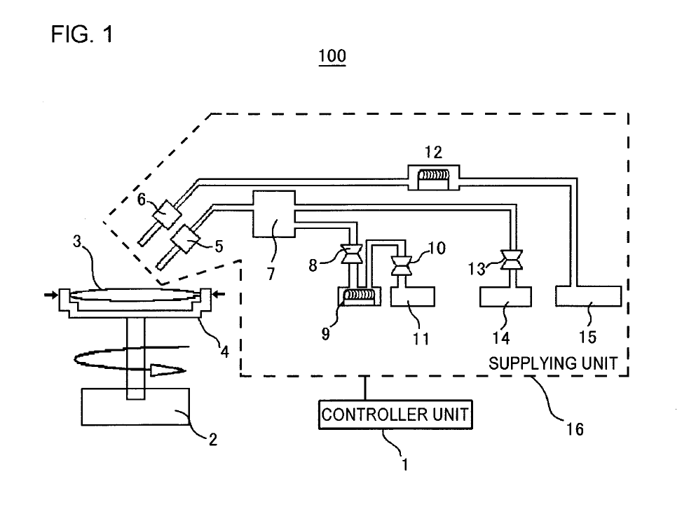

FIG. 1 is a schematic diagram, which schematically illustrates an example of an apparatus for processing a substrate according to the present embodiment. As shown in FIG. 1, an apparatus for processing a substrate 100 according to the present embodiment is a single wafer processing apparatus for processing a single wafer 3, and includes a support member 4, a motor 2, a supplying unit 16, and a controller unit 1.

The support member 4 is configured to support the wafer 3. Typical support member 4 may be, for example, a wafer chuck with clamping pins for supporting the wafer 3 by clamping the wafer by applying forces on the side surfaces of the wafer 3, as shown in FIG. 1. The support member 4 may be formed of a resin selected from a group consisting of, for example, tetrafluoroethylene-ethylene copolymer resin, chlorotrifluoroethylene resin tetrafluoroethylene-perfluoroalkylvinylether copolymer resin, polyetheretherketone resin, vinylidene fluoride resin, and polyvinylchloride resin.

The motor 2 is configured to rotate the support member 4. More specifically, the motor 2 rotates the support member 4 that is supporting the wafer 3.

The supplying unit 16 is configured to supply a liquid over the wafer 3 that is supported by the support member 4. The supplying unit 16 may include a first nozzle 5, a first supplying unit 7, a first reservoir unit 11, and a second reservoir unit 14. In addition, the supplying unit 16 may include a second nozzle 6. In addition, heaters 9 and 12 for heating the liquid, valves 8, 10 and 13 for controlling the flow of the liquid, and a third reservoir unit 15 for supplying a liquid to the second nozzle 6 may additionally be included.

The first nozzle 5 is configured to supply a first liquid or a second liquid over the wafer 3 supported by the support member 4. The first nozzle 5 may cause an oscillating action.

The first supplying unit 7 is configured to supply the first liquid or the second liquid to the first nozzle 5. The first nozzle 5, in turn, supplies the liquid, which is supplied from the first supplying unit 7, over the wafer 3. The first supplying unit 7 may be composed of, for example, a mixing valve, or may be composed of a tank that can contain a certain amount of a liquid.

The first reservoir unit 11 is configured of to supply a third liquid of, for example, sulfuric acid, to the first supplying unit 7. In addition, the second reservoir unit 14 is configured to supply a fourth liquid of, for example, an aqueous solution of hydrogen peroxide, to the first supplying unit 7.

Here, a liquid mixture obtained by mixing the third liquid and the fourth liquid may be employed for the first liquid supplied to the first nozzle 5 from the first supplying unit 7. For example, when sulfuric acid and an aqueous solution of hydrogen peroxide are employed as the third liquid and the fourth liquid, respectively, sulfuric acid-hydrogen peroxide mixture (SPM) containing major amount of peroxymonosulfuric acid (H₂SO₅: Caro's acid) created by a reaction of sulfuric acid with hydrogen peroxide may be created as the first liquid. Alternative first liquid may be, for example, hydrochloric acid-hydrogen peroxide mixture (HPM) created by mixing hydrochloric acid as the third liquid and an aqueous solution of hydrogen peroxide as the fourth liquid. For example, the fourth liquid (for example: aqueous solution of hydrogen peroxide) may be employed for the second liquid supplied to the first nozzle 5 from the first supplying unit 7.

The second nozzle 6 is configured to supply a fifth liquid to the wafer 3 supported by the support member 4. The fifth liquid supplied by the second nozzle 6 may be, for example, pure water, warm or hot water at a temperature ranging from 30 degrees C. to 95 degrees C., CO₂-water containing carbon dioxide or the like. The second nozzle 6 may cause an oscillating action.

The controller unit 1 provides a control of the supplying unit 16, in which the first liquid is supplied over the first wafer 3 for a predetermined time (arbitrarily selected), and then the second liquid or the fifth liquid is supplied over the first wafer 3 for a predetermined time (arbitrarily selected), and thereafter, the first liquid is supplied over the first wafer 3 for a predetermined time (arbitrarily selected). More specifically, the controller unit 1 controls the supplying unit 16 so as to carry out the above-described treatment for a single wafer 3.

A specific exemplary implementation of the above-described control in the controller unit 1 will be described below.

For example, the controller unit 1 provides a control, in which liquids (the third liquid (for example: sulfuric acid) and the fourth liquid (for example: aqueous solution of hydrogen peroxide)) are, first of all, supplied to the first supplying unit 7 from the first reservoir unit 11 and the second reservoir unit 14, and the liquid (the first liquid (for example: SPM solution)), which is supplied from the first supplying unit 7, is supplied over the wafer 3 supported by the support member 4 for a predetermined duration time. Then, the controller unit 1 provides a control, in which the supply of the liquid (the third liquid (for example: sulfuric acid)) from the first reservoir unit 11 to the first supplying unit 7 is stopped, while the supply of the liquid (the fourth liquid (for example: aqueous solution of hydrogen peroxide)) from the second reservoir unit 14 to the first supplying unit 7 is continued, and the liquid (the fourth liquid (for example: aqueous solution of hydrogen peroxide)) supplied from the first supplying unit 7 is ongoingly supplied over the wafer 3 supported by the support member 4 for a predetermined time as the second liquid. Then, the controller unit 1 provides a control, in which the supply of the liquid (the third liquid (for example: sulfuric acid)) from the first reservoir unit 11 to the first supplying unit 7 is started again, and sequentially, the liquid (the first liquid (for example: SPM solution) supplied from the first supplying unit 7 is supplied over the wafer 3 supported by the support member 4 for a predetermined time.

Alternative example may be that the controller unit 1 provides a control, in which the first liquid (for example: SPM solution) is, first of all, supplied over the wafer 3 from the first nozzle 5 for a predetermined time, and then the supply of the first liquid (for example: SPM solution) from the first nozzle 5 is stopped. Then, the controller unit 1 provides a control, in which the fifth liquid (for example: pure water) is supplied over the wafer 3 from the second nozzle 6 for a predetermined time, and then the supply of the fifth liquid (for example: pure water) from the second nozzle 6 is stopped. Then, the controller unit 1 instructs that the first liquid (for example: SPM solution) is supplied over the wafer 3 from first nozzle 5 again for a predetermined time.

While the types of the specific device for achieving the above-described control of the controller unit 1 is not particularly limited, an exemplary implementation may be that the switching of the first nozzle 5 and the second nozzle 6 is controlled by applying an electric signal. In addition, the valves 8, 10 and 13, switching of which is controllable by applying an electric signal, may be provided in a flow path connecting the first reservoir unit 11 with the first supplying unit 7 and in a flow path connecting the second reservoir unit 14 with the first supplying unit 7. The controller unit 1 may achieve the above-described control by controlling the switching of these nozzles and valves.

Next, the method for manufacturing the semiconductor device according to the present embodiment will be described.

The method for manufacturing the semiconductor device according to the present embodiment includes: a first removing operation of partially removing a first layer formed on a wafer supported by a support member by supplying a first liquid at a temperature of 60 degrees C. or higher over the wafer; an operation of cooling the wafer after the partially removing the first layer; and a second removing operation of removing the remaining portions of the first layer by supplying the first liquid at a temperature of 60 degrees C. or higher over the wafer after the cooling the wafer, the remaining portions of the first layer being remained after the partially removing the first layer.

The first liquid may typically be a SPM solution, a HPM solution or the like. The first layer may typically be a resist layer or the like. The operation of cooling the wafer may include an operation of supplying, over the wafer, an aqueous solution of hydrogen peroxide in a temperature that is lower than the temperature of the wafer at the time the first removing operation is finished, pure water, warm or hot water at a temperature ranging from 30 degrees C. to 95 degrees C., CO₂-water containing carbon dioxide or the like. The operation for cooling the wafer may be conducted immediately after the first removing operation is completed. The support member in this case may be the support member 4 of the above-described apparatus 100 for processing the substrate in the previous case of the present embodiment. In addition to above, the “predetermined time” appeared in the following descriptions of the respective operations may be suitably selected.

In addition to above, the method for manufacturing the semiconductor device of the present embodiment may be, for example, achieved by employing the above-described apparatus 100 for processing the substrate in the previous case of the present embodiment. More specifically, the method for manufacturing the semiconductor device of the present embodiment may be achieved by installing, in the apparatus 100 for processing the substrate, a computer program configured to perform a computer-implemented method for manufacturing a semiconductor device, including: partially removing a first layer formed on a wafer supported by a support member by supplying a first liquid at a temperature of 60 degrees C. or higher over the wafer; cooling the wafer after the partially removing the first layer; and removing the remaining portions of the first layer by supplying the first liquid at a temperature of 60 degrees C. or higher over the wafer after the cooling the wafer, the remaining portions of the first layer being remained after the partially removing the first layer, and by implementing such program with the apparatus 100 for processing a substrate. In addition to above, the method for manufacturing the semiconductor device of the present embodiment may be achieved by employing other type of apparatus other than the apparatus 100 for processing a substrate of the present embodiment.

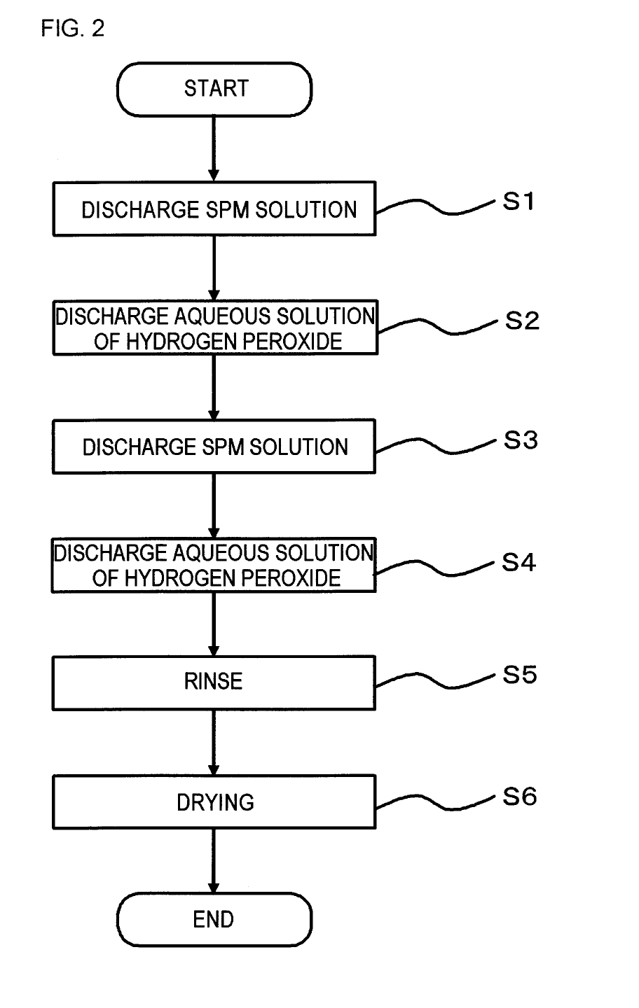

An example of the method for manufacturing the semiconductor device of the present embodiment will be specifically described. FIG. 2 is a flow chart of a wet processing in an example of the method for manufacturing the semiconductor device of the present embodiment.

The precondition is that sulfuric acid, the temperature of which is controlled at a predetermined temperature (for example: 80 degrees C. or higher), is stored in the first reservoir unit 11 shown in FIG. 1. Another precondition is that an aqueous solution of hydrogen peroxide at a temperature around the room temperature (about 25 degrees C.) is stored in the second reservoir unit 14. Once the valves 8, 10 and 13 are opened, then sulfuric acid and the aqueous solution of hydrogen peroxide flow through the first supplying unit 7 and are supplied toward the first nozzle 5 from the first supplying unit 7. In addition to above, the mixture of sulfuric acid and hydrogen peroxide is fully stirred during the flow from the first supplying unit 7 to the first nozzle 5. Such stirring causes sufficient mixing of sulfuric acid and hydrogen peroxide to create SPM containing major amount of peroxymonosulfuric acid (H₂SO₅: Caro's acid). Such generated SPM solution is discharged through the first nozzle 5 toward the surface of the wafer 3 supported by the support member 4. The temperature of the SPM solution is elevated to a temperature that is not lower than the temperature of sulfuric acid by a reaction heat generated in the reaction of sulfuric acid with hydrogen peroxide, and reaches to a temperature of about 150 to 160 degrees C. on the surface of the wafer 3.

Next, the process flow of the processing will be described. First of all, the wafer 3 is transported to the substrate processing unit 100 with a carrier robot (not shown), and the wafer 3 is transferred onto the support member 4. A resist layer, which is to be stripped, is formed on the surface of the wafer 3. Once the wafer 3 is supported by the support member 4, the motor 2 is actuated to start the rotation of the support member 4, namely the rotation of the wafer 3. The rotating speed of the wafer 3 may be increased to, for example, 1,000 rpm, and is maintained at 1,000 rpm. In addition, a mechanism (not shown) for moving the first nozzle 5 is actuated, so that the first nozzle 5 is disposed above the wafer 3 supported by the support member 4. Then, the valve 8 and the valve 13 are opened to supply the SPM solution from the first nozzle 5 over the surface of the wafer 3 in the rotating state (step S1).

In such case, the move of the first nozzle 5 may be stopped above the wafer 3 so that the SPM solution is supplied in the central section (around the center of rotation) of the surface of the wafer 3 from the first nozzle 5. In such case, the SPM solution supplied to the central section of the surface of the wafer 3 is subjected to centrifugal force generated by the rotation of the wafer 3 to flow along the surface of the wafer 3 toward the circumference thereof, spreading over the entire surface of the wafer 3. The resist formed on the surface of the wafer 3 is stripped by the stronger oxidizability of peroxymonosulfuric acid contained in the SPM solution, and the stripped resist material is, in turn, flushed away from the surface of the wafer 3 by the flow of the SPM solution to be removed therefrom.

The predetermined duration time for continuing the step S1 is typically determined as a time, which provides that the resist layer to be stripped is not completely stripped. For example, such predetermined duration time may be a half of the time required for completely stripping the resist layer to be stripped. More specifically, if it requires 120 seconds for completely strip the resist layer to be stripped, the step S1 for supplying the SPM solution over the wafer 3 while rotating the wafer 3 may continues for 60 seconds. Alternatively, such predetermined duration time may be a third, a fourth or less, of the time required for completely strip the resist layer to be stripped.

When a predetermined time (for example: 60 seconds) is elapsed after the supply of the SPM solution is started, the valve 8 is closed to present the situation, in which only the valve 13 is opened. In such situation, only the aqueous solution of hydrogen peroxide is supplied from the first nozzle 5 (step S2). In addition to above, the temperature of the surface of the wafer 3, at the time when a predetermined time (for example: 60 seconds) is elapsed after the supply of the SPM solution is started, reaches to about 150 to 160 degrees C. Thus, the surface of the wafer 3 is cooled by the supply of the aqueous solution of hydrogen peroxide (at about 25 degrees C.) over the wafer 3 in the step S2. In addition to above, the supply of the aqueous solution of hydrogen peroxide in the step S2 also serves as inducing a reaction of unreacted sulfuric acid remained on the wafer 3 with hydrogen peroxide.

While the predetermined duration time for continuing the step S2 may be suitably selected, such predetermined time for the step S2 may be, for example, 7 seconds or longer. The duration time shorter than the above-described time (7 seconds) may potentially cause insufficient cooling of the surface of the wafer 3. Further, the predetermined duration time for continuing the step S2 may be, for example, 12 seconds or shorter. While the duration time longer than the above-described time (12 seconds) is preferable in one way in terms of providing sufficient cooling of the surface of the wafer 3, such longer duration time is not preferable, since the longer processing time results in a decreased process efficiency and also results in wasted consumption of the aqueous solution of hydrogen peroxide, leading to an increased production cost. That is, the predetermined time for continuing the step S2 may be equal to or longer than 7 seconds and equal to or shorter than 12 seconds.

Then, the valve 8 is opened again to start the supply of the SPM solution from the first nozzle 5 over the surface of the wafer 3 in the rotating state (step S3). In such case, the movement of the first nozzle 5 may be stopped above the wafer 3 to supply the SPM solution in the central section (around the center of rotation) of the surface of the wafer 3 from the first nozzle 5. In such case, the SPM solution supplied to the central section of the surface of the wafer 3 is subjected to centrifugal force generated by the rotation of the wafer 3 to flow along the surface of the wafer 3 toward the circumference thereof, spreading over the entire surface of the wafer 3. The resist formed on the surface of the wafer 3 is stripped by the stronger oxidizability of peroxymonosulfuric acid contained in the SPM solution, and the stripped resist is, in turn, flushed away from the surface of the wafer 3 by the flow of the SPM solution, thereby being removed therefrom.

The predetermined time for continuing the step S3 may be determined that, for example, the combination of the time for S3 with the predetermined time for conducting the step S1 would satisfy the time required for completely stripping the resist layer to be stripped. For example, if it requires 120 seconds for completely stripping the resist layer to be stripped, and when the step S1 has been conducted for 60 seconds, the SPM solution may be supplied over the wafer 3 while rotating the wafer 3 for 60 seconds in the step S3. In such case, the process for manufacturing the semiconductor device of the present embodiment achieves the complete stripping of the resist layer to be stripped formed on the wafer 3 in the step S1 and the step S3.

Alternatively, the process for manufacturing the semiconductor device of the present embodiment may be configured that, after the first implementation of the step S3, the combination of the step S2 and the step S3 may be repeated for a predetermined cycles. More specifically, the processing for supplying the SPM solution over the wafer 3 may be conducted for three or more cycles. In the case that three or more cycles of the processing for supplying the SPM solution over the wafer 3 are conducted, the processing for cooling the wafer with an aqueous solution of hydrogen peroxide is conducted after each of the processing for supplying the SPM solution.

Typical post processing after the step S3 may be, for example, that the valve 8 is closed to present the situation, in which only the valve 13 is opened. This causes that only aqueous solution of hydrogen peroxide is supplied from the first nozzle 5 over the surface of the wafer 3 (step S4). Such processing achieves the cooling of the surface of the wafer 3. In addition to above, the supply of the aqueous solution of hydrogen peroxide in the step S4 also serves as inducing a reaction of unreacted sulfuric acid remained on the wafer 3 with hydrogen peroxide.

While the predetermined duration time for continuing the step S4 may be suitably selected, such predetermined time for the step S4 may be, for example, equal to or longer than 7 seconds and equal to or shorter than 12 seconds. The reason for selecting such time duration is substantially identical to that for the step S2.

Thereafter, the first nozzle 5 is closed to stop the supply of the aqueous solution of hydrogen peroxide, and then the first nozzle 5 is retracted to a position that is offset from the space above the wafer 3. Then, pure water is supplied toward the center of the surface of the wafer 3 from the second nozzle 6. The pure water supplied over the surface of the wafer 3 is subjected to centrifugal force generated by the rotation of the wafer 3 to flow along the surface of the wafer 3 toward the circumference thereof. This allows the pure water rapidly spreading over the entire area of the surface of the wafer 3, so that the SPM solution, the aqueous solution of hydrogen peroxide and the like sticking onto the surface of the wafer 3 are washed away with the pure water (rinse processing: step S5). The predetermined duration time for continuing the step S5 may be suitably selected.

After the start of the supply of the pure water, and when 60 seconds, for example, has been elapsed, then the rotation speed of the wafer 3 is increased to a predetermined spinning drying rotation speed (within a range of 1,000 to 3,000 revolutions per minute (rpm)) to conduct a spinning dry processing for spinning the pure water off via a centrifugal force (drying processing: step S6). Such spinning dry processing may be continued for a duration time of, for example, within a range of from 10 seconds to 60 seconds, and typically for 30 seconds, for example. After the spinning dry processing, the motor 2 is stopped, and once the wafer 3 comes to rest, the processed wafer 3 is unloaded from the apparatus 100 for processing the substrate with a carrier robot (not shown).

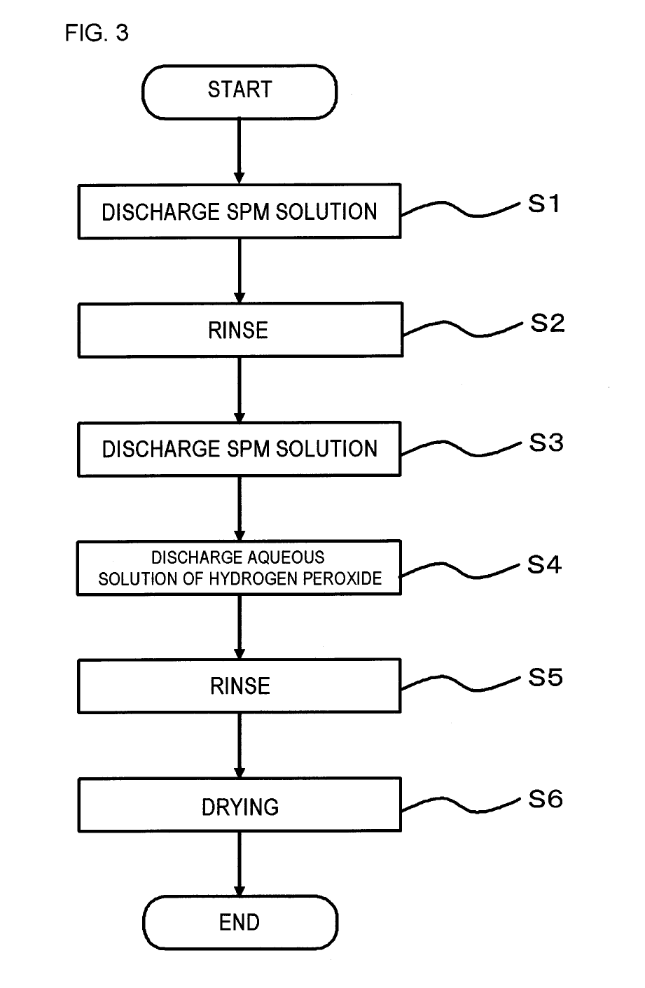

While the step S2 involves supplying the second liquid (the aqueous solution of hydrogen peroxide) over the wafer 3 from the first nozzle 5 in the above-described embodiments of the process for manufacturing the semiconductor device, the step S2 may alternatively involve other type of processing. The other type of processing may typically involves that the fifth liquid (for example:pure water) is supplied (rinse) from the second nozzle 6 instead of the second liquid in the step S2, as shown in the flow chart of the wet processing in FIG. 3. The temperature of the pure water may be maintained at around the room temperature (about 25 degrees C.).

Nevertheless, the processing of supplying the second liquid over the wafer 3 from the first nozzle 5 as in the above-described embodiment of the process for manufacturing the semiconductor device is desirable, since the time required for the movements of the first nozzle 5 and the second nozzle 6 for changing the fifth liquid from the first liquid and/or the time required for the control of the switching of the nozzles can be reduced, resulting in an improved processing efficiency.

Next, advantageous effects obtainable by conducting the process for manufacturing the semiconductor device of the present embodiment will be described on the basis of the following results of the experiments.

<<Experiment 1: Relation of the Durability of the Support Member for Supporting the Wafer with the Temperature of the Liquid Supplied Over the Wafer>>

### <Samples>

Three types of wafer chucks with clamping pins, manufactured of a material A, a material B, and a material C, respectively, were prepared. The material A is tetrafluoroethylene-ethylene copolymer resin, the material B is chlorotrifluoroethylene resin, and the material C is tetrafluoroethylene perfluoroalkylvinylether copolymer resin.

### <Methods for Experiments>

5,000 process cycles were conducted for each of the SPM solutions of 60 degrees C., 80 degrees C., 100 degrees C., 140 degrees C., and 160 degrees C., where one cycle consists of: the processing with the SPM solution for 60 seconds; and then the rinse processing with pure water for 30 seconds; and the drying processing for 20 seconds, and after the respective 5,000 cycles, the measurements of loads were conducted with a load measurement apparatus.

### <Discussion>

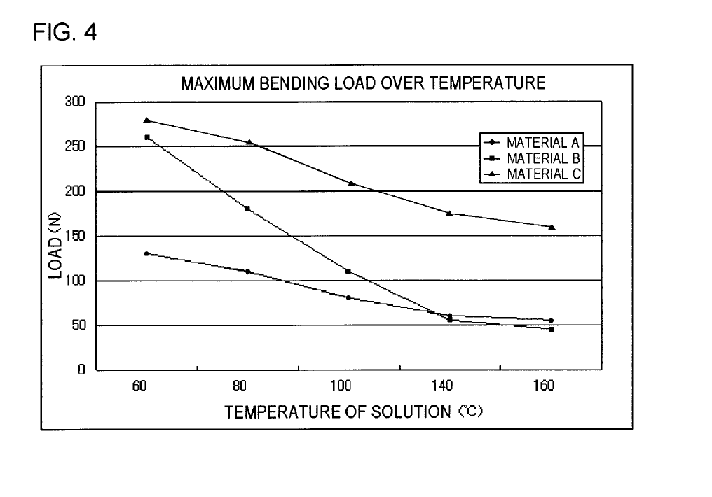

Results of the experiments are shown in FIG. 4. As shown in the graph, it is understood that the durability is deteriorated when the temperature of the SPM solution is increased to exceed 60 degrees C. in each of the wafer chucks with clamping pins composed of the material A, the material B, and the material C. In addition, it is also understood that higher temperature of the SPM solution causes more severe deterioration of each of the wafer chucks with clamping pins composed of the material A, the material B, and the material C. That is, it is understood that the implementation of the wet processing employing the SPM solution of 60 degrees C. or higher accelerates the deterioration of the wafer chuck with clamping pins.

In addition to above, the present inventors confirmed that similar results were obtained by the wafer chuck with clamping pins formed of any one of polyetheretherketone resin, vinylidene fluoride resin, and polyvinylchloride resin.

<<Experiment 2: The Temperature Changes of the Wafer Supported by the Support Member in the Wet Processing, and Changes of Durability of the Support Member and Stripping-Ability for the Resist Layer Over Different Time Durations for Continually Supplying the Liquid Over the Wafer in the Wet Processing>>

### <Samples>

Support member: a wafer chuck with clamping pins formed of tetrafluoroethylene perfluoroalkylvinylether copolymer resin was prepared.

Wafer: a resist was formed as a layer to be stripped on a silicon substrate. Thereafter, a predetermined aperture was formed in the resist, and an ion implantation process was conducted for the silicon substrate through a mask of such resist. The employed ion species was arsenic (As), and the employed resist was a resist for krypton fluoride (KrF) radiation.

### <Wet Processing>

The SPM solution and warm water were employed to conduct the wet processing for stripping the resist formed on the wafer for the above-described wafer supported by the above-described support member. The processing conditions were as follows.

SPM composition: an aqueous solution containing sulfuric acid at 96% wt. and an aqueous solution containing hydrogen peroxide at 31% wt. were mixed at a volumetric ratio of 2:1.

Quantity of SPM discharging over the surface of the wafer: 0.9 liter/min.

Heating temperature for sulfuric acid: 95 degrees C.

Temperature of SPM: 120 to 220 degrees C.

### <Experiment 2-1>

The temperature changes of the wafer supported by the wafer chuck with clamping pins in the wet processing were measured. More specifically, the SPM solution was supplied over the wafer for about 60 seconds under the above-described processing conditions (SPM solution-supplying processing), and then pure water of a temperature controlled to about 25 degrees C. was supplied over the wafer for about 10 seconds (rinse processing), and the temperature changes occurred on the wafer during these processing were measured. The measurements of the temperature changes were conducted by measuring the temperature of the substantially central section of the wafer with an infrared-ray radiation thermometer.

### <Discussion of Experiment 2-1>

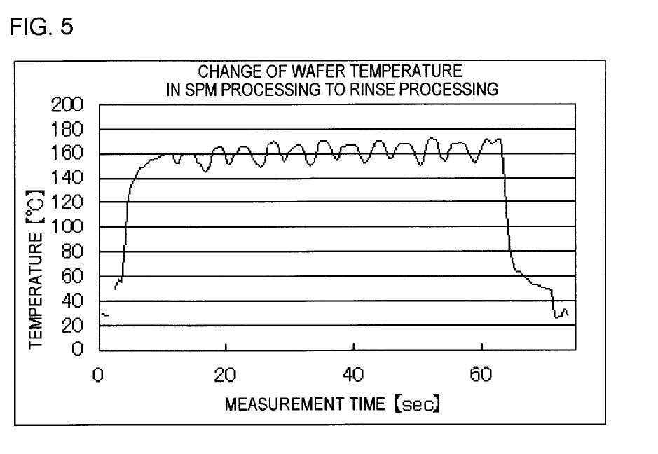

FIG. 5 shows the temperature changes of the wafer during the SPM solution-supplying processing and during the rinse processing. The temperature of the wafer is considerably elevated in the initial duration of about 10 seconds after the supply of the SPM solution is started. Then, it is the tendency that temperature is gradually increased in the subsequent term of about 50 seconds thereafter. The temperature of the wafer is, in turn, considerably decreased to around 40 to 50 degrees C. by the subsequent rinse processing continued for about 7 to 10 seconds. In addition to above, it was confirmed that similar results were also obtained in the case that an aqueous solution of hydrogen peroxide of a temperature controlled to about 25 degrees C. was supplied over the wafer, instead of conducting the rinse processing.

More specifically, it can be understood that the wafer of the elevated temperature of about 160 degrees C. due to the SPM solution-supplying processing can be sufficiently cooled by the supply of pure water or aqueous solution of hydrogen peroxide of a temperature controlled to about 25 degrees C. over the wafer continued for 7 to 10 seconds.

In addition to above, the present inventors confirmed that similar results were obtained by the implementations of supporting the wafer on the respective wafer chucks with clamping pins formed of a resin selected from a group consisting of tetrafluoroethylene-ethylene copolymer resin, chlorotrifluoroethylene resin, polyetheretherketone resin, vinylidene fluoride resin, and polyvinylchloride resin.

### <Experiment 2-2>

Relations of the durability of the wafer chuck with clamping pins that supports the wafer with the duration time for continually supplying the SPM solution over the wafer were measured. More specifically, 5,000 cycles of the wet processing, each of which involves continually supplying the SPM solution over the wafer for 120 seconds, were conducted for one sample (wafer chuck with clamping pins) under the above-described processing conditions. Besides, 10,000 cycles of another wet processing, each of which involves continually supplying the SPM solution over the wafer for 60 seconds, were conducted for another sample (wafer chuck with clamping pins). In addition to above, the cooling processing for supplying an aqueous solution of hydrogen peroxide of a temperature controlled to about 25 degrees C. over the wafer was conducted for about 7 seconds after the respective SPM solution-supplying processing.

Thereafter, the measurements of the durability of the respective wafer chucks with clamping pins were conducted. The measurements of the durability were conducted by employing the method for measuring the loads, which is similar as the method employed in the above-described experiment, and the durability was represented by a ratio of the measured load over a load of a new and unused wafer chuck with clamping pins as a reference.

### <Discussion of Experiment 2-2>

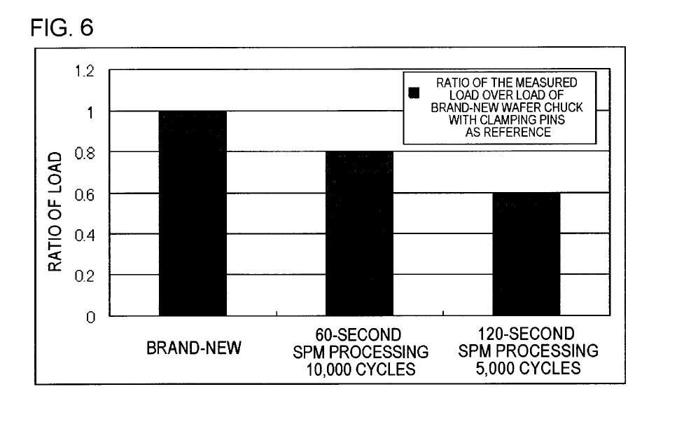

FIG. 6 shows relations of the durability of the wafer chuck with clamping pins for supporting the wafer over the time duration for continually supplying the SPM solution over the wafer. As shown in the graph, it can be understood that the durability of the wafer chuck with clamping pins is further deteriorated as the cycles of the wet processing employing the SPM solution are repeatedly conducted. It can also be understood that shorter duration time for continually supplying the SPM solution over the wafer provides reduced deterioration of the durability of wafer chuck with clamping pins.

More specifically, it can be understood that the process involving the multiple SPM solution-supplying processing and the cooling processing carried out after the respective SPM solution-supplying processing as in the present embodiment allows reducing an accelerated deterioration of the wafer support member such as wafer chuck with clamping pins, as compared with the process involving single-continuous implementation of the SPM solution-supplying processing for the wafer.

In addition to above, the present inventors confirmed that similar results were obtained by the implementations of supporting the wafer on the respective wafer chucks with clamping pins formed of a resin selected from a group consisting of tetrafluoroethylene-ethylene copolymer resin, chlorotrifluoroethylene resin, polyetheretherketone resin, vinylidene fluoride resin, and polyvinylchloride resin.

### <Experiment 2-3>

Experiments for the stripping-ability of the resists processed by the process of multiple separate implementations of the SPM solution-supplying processing for a single wafer were conducted. More specifically, the 120 second-processing for supplying the SPM solution for a single wafer was split into two implementations under the above-described processing condition. That is, two implementation of the SPM solution-supplying processing for 60 seconds were carried out for a single wafer. The cooling processing by supplying the aqueous solution of hydrogen peroxide of a temperature controlled to about 25 degrees C. over the wafer was conducted for a predetermined time after each of the implementations of the SPM solution-supplying processing. Thereafter, the particles adhered onto the surface of the processed wafer were counted by employing a wafer inspection apparatus.

Results are shown in Table 1, indicating as “first example”. Table 1 shows the natures of the processing and the processing time of the corresponding processing. The time-series progression of the process is presented in this table from the left side toward the right side. The blanked square in the table with no processing time indicates that no processing is conducted. The evaluation of the stripping-ability shown in the table are presented by the following two ratings.

◯ (circle): substantially no particle is generated; and
Δ (triangle):while a visual inspection presents that the resist is stripped off, a residual material of the stripping is found by an inspection with a particle inspection device.

TABLE 1

| | | | | HYDROGEN | | | |
|---|---|---|---|---|---|---|---|
| | SPM | SPM | SPINNING- | PEROXIDE | | SPINNING- | SPM |
| | PROCESSING 1 | PUDDLING 1 | OFF 1 | PROCESSING 1 | RINSE 1 | OFF 2 | PROCESSING 2 |
| EXAMPLE 1 | 60 SEC. | | | 7 SEC. | | | 60 SEC. |
| EXAMPLE 2 | 60 SEC. | | | | 7 SEC. | | 60 SEC. |
| COMPARATIVE | 60 SEC. | | | 10 SEC. | | | |
| EXAMPLE 1 | | | | | | | |
| COMPARATIVE | 60 SEC. | 10 SEC. | 10 SEC. | | — | — | 60 SEC. |
| EXAMPLE 2 | | | | | | | |

| | HYDROGEN | | | | TOTAL | |
|---|---|---|---|---|---|---|
| | PEROXIDE | SPM | | | PROCESSING | STRIPPING- |
| | PROCESSING 2 | PUDDLING 2 | RINSE 2 | DRY | TIME | ABILITY |
| EXAMPLE 1 | 10 SEC. | | 30 SEC. | 30 SEC. | 197 SEC. | ◯ |
| EXAMPLE 2 | 10 SEC. | | 30 SEC. | 30 SEC. | 187 SEC. | ◯ |
| COMPARATIVE | | | 30 SEC. | 30 SEC. | 130 SEC. | Δ |
| EXAMPLE 1 | | | | | | |
| COMPARATIVE | | 10 SEC. | 30 SEC. | 30 SEC. | 210 SEC. | Δ |
| EXAMPLE 2 | | | | | | |

In addition to above, a result of an implementation of a single 60-second processing for supplying the SPM solution for a single wafer is presented as comparative example 1 in Table 1. Further, a result of an implementation of a wet processing on the basis of the technology described in Japanese Patent Laid-Open No. 2007-234,812 is also presented as comparative example 2 in Table 1.

Further, a result of a process involving double implementations of 60-second processing for supplying the SPM solution for a single wafer and an implementation of a cooling processing (rinse) with pure water of a temperature controlled to about 25 degrees C. after the first implementation of the SPM solution-supplying processing is presented as example 2.

### <Discussion of Experiment 2-3>

While sufficient stripping-ability is not obtained in the process of a single implementation of 60-second processing for supplying the SPM solution (comparative example 1), examples 1 and 2, which involve double implementations of 60-second processing for supplying the SPM solution, achieve sufficient stripping-ability, as shown in Table 1. In addition to above, it is confirmed that a sufficient stripping-ability is obtained by conducting double implementation of the processing of comparative example 1. While double implementation of the SPM solution-supplying processing for 60 seconds were also conducted in comparative example 2, sufficient stripping-ability was not achieved in comparative example 2. In comparative example, no implementation for supplying an aqueous solution of hydrogen peroxide (hydrogen peroxide processing) after the supply of the SPM solution in comparative example 2 leads to insufficient removal of sulfuric acid from the surface of the wafer even though a spinning-off processing or a rinse processing with pure water is conducted, causing a generation of particles due to residual sulfuric acid on the surface of the wafer. Therefore, it is considered that the reason for the insufficient stripping-ability in comparative example 2 is the generated particles.

Further, it is also understood according to Table 1 that examples 1 and 2 require reduced total processing time that is shorter by about 15 to 20 seconds than comparative example 2, while sufficient stripping-ability is achieved. Meanwhile, although the processing of comparative example 1 can also achieves similar level of the stripping-ability as obtained in examples 1 and 2 by conducting double implementations of the processing, the processing time required for the double implementations is 260 seconds, and thus longer time is required in such double implementation of the processing of comparative example 1, as compared with examples 1 and 2.

Therefore, according to the process for manufacturing the semiconductor device of the present embodiment, the wet processing with sufficient stripping-ability can be achieved in effective manner.

It is understood from the above-described examples 1 and 2 that, according to the process for manufacturing the semiconductor device of the present embodiment, the layer of the stripping object such as a resist layer and the like can be sufficiently removed and accelerated deterioration of the support member for supporting the wafer can be inhibited.

It is apparent that the present invention is not limited to the above embodiment, and may be modified and changed without departing from the scope and spirit of the invention.

What is claimed is:

1. A method for manufacturing a semiconductor device, comprising:
partially removing a first layer formed on a wafer supported by a support member by supplying a first liquid at a temperature of 60 degrees C. or higher over said wafer;
cooling said wafer after said partially removing the first layer; and
removing the remaining portions of the first layer by supplying the first liquid at a temperature of 60 degrees C. or higher over said wafer after said cooling the wafer, said remaining portions of the first layer being remained after said partially removing the first layer.

2. The method for manufacturing the semiconductor device as set forth in claim 1, wherein the first liquid is sulfuric acid-hydrogen peroxide mixture (SPM).

3. The method for manufacturing the semiconductor device as set forth in claim 2, wherein said first layer is a resist layer.

4. The method for manufacturing the semiconductor device as set forth in claim 1, wherein said cooling the wafer includes supplying an aqueous solution of hydrogen peroxide or pure water over said wafer, at a temperature of lower than the temperature of said wafer at the time said partially removing the first layer is ended.

5. The method for manufacturing the semiconductor device as set forth in claim 1, wherein said support member is formed of a resin selected form a group consisting of: tetrafluoroethylene-ethylene copolymer resin, chlorotrifluoroethylene resin, tetrafluoroethylene-perfluoroalkylvinylether copolymer resin, polyetheretherketone resin, vinylidene fluoride resin and polyvinylchloride resin.

6. The method for manufacturing the semiconductor device as set forth in claim 1, wherein said cooling the wafer is conducted immediately after said partially removing the first layer is ended.

7. The method for manufacturing the semiconductor device as set forth in claim 6, wherein said partially removing the first layer includes supplying a mixture solution of sulfuric acid and an aqueous solution of hydrogen peroxide over said wafer, said solution being supplied from a first reservoir unit for retaining sulfuric acid and a second reservoir unit for retaining an aqueous solution of hydrogen peroxide, and said cooling the wafer includes supplying only the aqueous solution of hydrogen peroxide supplied from said second reservoir unit over said wafer, by stopping the supply of sulfuric acid from said first reservoir unit in the ongoing operation continued after said partially removing the first layer.

8. An apparatus for processing a substrate, comprising:
a support member for supporting a wafer;
a motor for rotating said support member;
a supplying unit for supplying a liquid over said wafer; and
a controller unit for controlling a type of a liquid supplied from said supplying unit and a duration time of the supply,
wherein said controller unit provides a control, in which
a first liquid is supplied over said wafer for a predetermined time, and then a liquid at a temperature of lower than the temperature of the wafer is supplied over said wafer for a predetermined time, and then the first liquid is supplied over said wafer for a predetermined time.

9. The apparatus for processing the substrate as set forth in claim 8, wherein said supplying unit comprises: a first nozzle for supplying the first liquid or said liquid at a temperature of lower than the temperature of the wafer as a second liquid over the wafer supported by said support member; a first supplying unit for supplying the first liquid or the second liquid to said first nozzle; first reservoir unit for supplying a third liquid to said first supplying unit; and a second reservoir unit for supplying a fourth liquid to said first supplying unit, and
wherein said controller unit provides a control, in which, a liquid is supplied to said first supplying unit from said first reservoir unit and said second reservoir unit and the liquid supplied from said first supplying unit is supplied over said wafer as the first liquid from said first nozzle for a predetermined time, and then the supply of the third liquid from said first reservoir unit to said first supplying unit is stopped, and sequentially, the fourth liquid supplied from said first supplying unit is supplied over said wafer as the second liquid from said first nozzle for a predetermined time, and then the supply of the third liquid from said first reservoir unit to said first supplying unit is restarted, and subsequently, the liquid supplied from said first supplying unit is supplied over said wafer as the first liquid from said first nozzle for a predetermined time.

10. The apparatus for processing the substrate as set forth in claim 9, wherein the third liquid is sulfuric acid, and the fourth liquid is an aqueous solution of hydrogen peroxide.

11. The apparatus for processing the substrate as set forth in claim 8, wherein said supplying unit comprises a first nozzle for supplying the first liquid over the wafer supported by said support member and a second nozzle for supplying said liquid at a temperature of lower than the temperature of the wafer as a fifth liquid over the wafer supported by said support member, and said controller unit provides a control, in which the first liquid is supplied from said first nozzle over said wafer for a predetermined time, and then the supply of the first liquid from said first nozzle is stopped, and then the fifth liquid is supplied from said second nozzle for a predetermined time, and then the supply of the fifth liquid from said second nozzle is stopped while the first liquid is supplied over said wafer from said first nozzle for a predetermined time

12. The apparatus for processing the substrate as set forth in claim 11, wherein the first liquid is sulfuric acid-hydrogen peroxide mixture (SPM), and the fifth liquid is pure water.

13. The apparatus for processing the substrate as set forth in claim 8, wherein said support member is formed of a resin selected form a group consisting of: tetrafluoroethylene-ethylene copolymer resin, chlorotrifluoroethylene resin, tetrafluoroethylene-perfluoroalkylvinylether copolymer resin, polyetheretherketone resin, vinylidene fluoride resin and polyvinylchloride resin.

14. A computer readable medium storing a computer program product configured to perform a computer-implemented method for manufacturing a semiconductor device, comprising:
partially removing a first layer formed on a wafer supported by a support member by supplying a first liquid at a temperature of 60 degrees C. or higher over said wafer;
cooling said wafer after said partially removing the first layer; and
removing the remaining portions of the first layer by supplying the first liquid at a temperature of 60 degrees C. or higher over said wafer after said cooling the wafer, said remaining portions of the first layer being remained after said partially removing the first layer.
